(19) United States
(12) Patent Application Publication
(10) Pub. No.: US 2014/0159047 A1
(43) Pub. Date: Jun. 12, 2014

(54) MANUFACTURING PROCESS OF OXIDE INSULATING LAYER AND FLEXIBLE STRUCTURE OF LTPS-TFT (LOW-TEMPERATURE POLYCRYSTALLINE SILICON THIN FILM TRANSISTOR) DISPLAY

(71) Applicants: Hao WANG, Wuhan (CN); Wen-Shiang Liao, Miaoli County (TW); Yue-Gie Liaw, Miaoli County (TW)

(72) Inventors: Hao WANG, Wuhan (CN); Wen-Shiang Liao, Miaoli County (TW); Yue-Gie Liaw, Miaoli County (TW)

(21) Appl. No.: 13/707,804

(22) Filed: Dec. 7, 2012

(51) Int. Cl. H01L 29/04; H01L 21/02

(52) U.S. Cl. CPC H01L 29/04; H01L 21/02381
USPC 257/75; 438/487

(57) ABSTRACT

The present invention provides a manufacturing process of oxide insulating layer and flexible structure of LTPS-TFT display. The manufacturing process firstly provides a substrate, which is a soft material sheet; and then an a-Si layer is formed on the substrate, and oxygen ion implantation process of a certain depth is conducted onto the a-Si layer; finally, ELA process is conducted to transform a-Si layer into a Poly-Si layer and an oxide insulating layer; of which the oxide insulating layer is a silica insulating layer and located within the Poly-Si layer for subsequently producing LTPS-TFT; the structure comprises of a substrate, Poly-Si layer and oxide insulating layer within the Poly-Si layer.

### BACKGROUND OF INVENTION

1. Field of the Invention

The present invention relates generally to an LCD technology, and more particularly to an oxide insulating layer manufacturing process and soft or flexible structure of LTPS-TFT display.

2. Description of Related Art

TFT-LCD (Thin Film Transistor Liquid Crystal Display) has become a main stream of displays depending on its lightweight, thin-profile, low power consumption and low radiation. Thus, it is widely used in notebook computers, desktop computers, DVD players and digital cameras, etc. Today, as for TFT-LCD, most of pixel control switches are made of a-Si (amorphous silicon) transistors. With people's demanding requirements for the picture quality of display, it is difficult to realize high-resolution manufacturing process and better electrical characteristics owing to limited properties of a-Si transistor. In this background, LTPS-TFT has been launched into the market. Although a-Si TFT-LCD takes a leading position at present, poly-Si TFT-LCD shows a better picture quality and significant potential strength due to fast response speed, high-brightness, high-resolution, energy-saving and many other advantages. In recent years, LTPS-TFT is extended to employ current-driven OLED (Organic Light-Emitting Diode) displays, since as compared with other panel display technologies, OLED display panel could obtain full-color images with high-brightness, high clarity and faster response speed. Due to its characteristics including simple structure and self-illumination, the production cost of OLED display panel is approximately 30-40% lower than TFT-LCD, so it could be widely used in mobile phones, MP3 players and so on.

There are many conventional methods of producing poly-Si thin films, e.g.: poly-Si film could be transformed from a-Si film by using high temperature, known as SPC (Solid Phase Crystallization); a-Si film is partly irradiated by CW or pulse laser beam, then melted and finally solidified into a poly-Si film, called LC (Laser Crystallization); the a-Si is recrystallized by using metal induction in low temperature, and then transformed into a poly-Si film, called MILC (Metal Induced Lateral Crystallization); film recrystallization could be conducted by using photomask to control laser output shape in cooperation with movement of the substrate, named SLS (Sequential Lateral Solidification) technology.

However, the ELA (Excimer Laser Annealing) is generally used for producing poly-Si film, since it belongs to ultraviolet band and has a high pulse energy, enabling to effectively transform a-Si thin film into poly-Si thin film; also, a-Si film on glass substrate could be turned into poly-Si thin film via annealing, thereby reducing the overall manufacturing cost. Usually, after irradiation of the Excimer laser, the a-Si thin film could be quickly heated up to 1400° C. and melted. In tens of nanoseconds after laser pulsing, it starts to be solidified into poly-Si.

The conventional LTPS-TFT generally employs silica as substrate, therefore, the overall structure has no flexibility, and could not be applied to flexible display or other electronic products requiring for flexibility (e.g. fingerprint sensor).

Thus, to overcome the aforementioned problems of the prior art, it would be an advancement if the art to provide an improved structure that can significantly improve the efficacy.

Therefore, the inventor has provided the present invention of practicability after deliberate design and evaluation based on years of experience in the production, development and design of related products.

### SUMMARY OF THE INVENTION

The main purpose of the present invention is to provide a manufacturing process of oxide insulating layer and flexible structure of LTPS-TFT display, which could produce poly-Si layer and oxide insulating layer on soft substrate for subsequent manufacturing of LTPS-TFT display; and its flexible structure could be used in flexible displays and other electronic products for higher practical value.

To this end, the present invention provides a manufacturing process of oxide insulating layer of LTPS-TFT display, which comprising: providing a substrate, which is a soft material sheet; an a-Si layer is formed on the soft or flexible substrate; oxygen ion implantation process of a certain depth is conducted on the a-Si layer; ELA process is conducted to transform a-Si layer into a poly-Si layer and an oxide insulating layer; of which the oxide insulating layer is a silica (SiO2) insulating layer located within the poly-Si layer.

Furthermore, the substrate can be a soft and flexible metal foil, a plastic film, a polyester sheet, a rayon cloth, or a fiber cloth.

Furthermore, the a-Si layer is deposited via PECVD.

Furthermore, the oxygen ion implantation process is realized by means of SIMOX (Silicon Implanted Oxide).

Furthermore, the ELA process is realized by firstly pre-cleaning and then by laser annealing.

In addition, the present invention also provides a flexible structure of the LTPS-TFT, including: a flexible substrate, which is a soft metal foil, plastic film, polyester sheet, rayon cloth, or fiber cloth; a poly-Si layer, located on the flexible substrate; an oxide insulating layer, located in the poly-Si layer.

Furthermore, the oxide insulating layer is a silica (SiO2) insulating layer.

### BRIEF DESCRIPTION OF THE DRAWINGS

FIGS. 1-3 is structural diagrams of manufacturing process of a preferred embodiment of the present invention.

### DETAILED DESCRIPTION OF THE INVENTION

The present invention will be more readily understood upon detailed description of two preferred embodiments of the present invention with reference to the accompanying drawings, wherein:

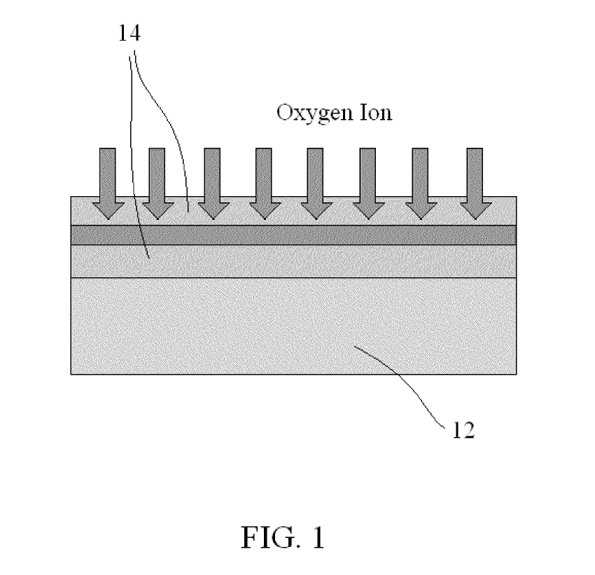

FIG. 1 depicts the manufacturing process of the oxide insulating layer of LTPS-TFT display in a preferred embodiment of the present invention, including:

Step 1 (Provide a substrate 12): the substrate 12 is a soft material sheet, such as a soft metal foil, plastic film, polyester sheet, rayon cloth, or fiber cloth, . . . , etc., since the soft substrate foil is characterized by strong resistance to high temperature, acid and alkali.

Step 2 (an a-Si layer 14 is formed on the substrate 12): an a-Si layer 14 is deposited on the top of the substrate 12 via PECVD. Said PECVD is one of basic methods for material surface modification and thin film deposition. As the device is employed in high vacuum environment (the device is filled with SiH₄+NH₃ or N₂O, H₂, N₂), the deposition thin films has good characteristics such as high quality and fewer impurity.

Step 3 (oxygen ion implantation process of a certain depth is conducted on the a-Si layer 14): a high-dose and low-energy oxygen ion implantation (Gaussian distribution) of preset depth is conducted on the a-Si layer 14 via the SIMOX of conventional semiconductor. This is realized in a way that the a-Si layer 14 is bombarded by oxygen ion to implant the oxygen ion into the a-Si layer 14.

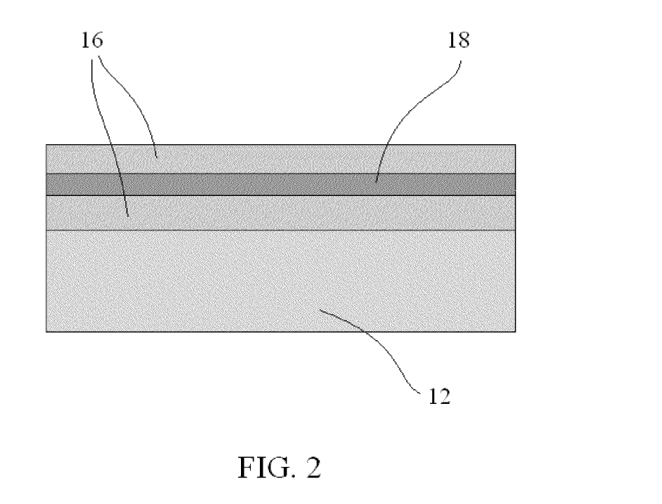

Step 4 (conduct the ELA process): the a-Si layer 14 is transformed into a poly-Si layer 16 and an oxide insulating layer 18 via the ELA technology. Referring to FIG. 2, the oxide insulating layer 18 is a silica insulating layer located within the poly-Si layer 16. Referring to Table 1, the steps of ELA technology are as follows: firstly, pre-clean O₃, DHF (1%), and then high energy generated by instant laser pulse wave is irradiated into the surface of the a-Si layer 14. Heat effect is generated only on the surface of the A-Si layer 14, making it reach instantaneously over 1000° C. and transform a-Si into p-Si.

In this way, it could be used subsequently for producing conventional LTPS-TFT display.

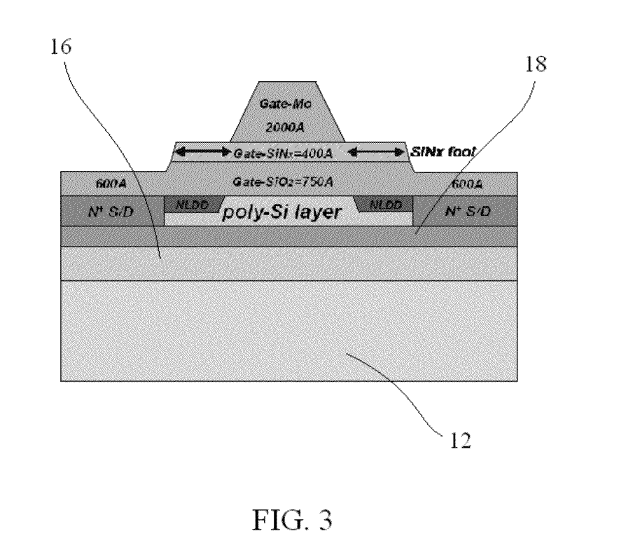

Accordingly, the present invention provides a manufacturing process of oxide insulating layer of LTPS-TFT display, which skillfully employs the SIMOX technology of conventional semiconductor (SOI wafer) in cooperation with ELA technology, so poly-Si layer 16 and oxide insulating layer 18 could be manufactured on the soft substrate 12 for subsequent manufacturing process of the LTPS-TFT display, as shown in FIG. 3.

The present invention could also provide a flexible structure of LTPS-TFT display; referring to FIG.2, it comprises: a substrate 12, a poly-Si layer 16 set on the substrate 12 and an oxide insulating layer 18 located within the poly-Si layer 16. The flexible structure could be used in flexible display and other electronic products (e.g. fingerprint sensor).

To sum up, the present invention provides a manufacturing process of oxide insulating layer and flexible structure of the LTPS-TFT display, which could produce poly-Si layer and oxide insulating layer on soft substrate by using SIMOX and ELA technology for subsequent manufacturing of LTPS-TFT display. The flexible structure could be used in flexible displays and other electronic products for higher practical value.

Although the invention has been explained in relation to its preferred embodiment, it is to be understood that many other possible modifications and variations can be made without departing from the spirit and scope of the invention as hereinafter claimed. Although the invention has been explained in relation to its preferred embodiment, it is to be understood that many other possible modifications and variations can be made without departing from the spirit and scope of the invention as hereinafter claimed.

What is claimed is:

1. A manufacturing process of oxide insulating layer of LTPS-TFT display, which comprises at least the following steps:
providing a substrate which is a soft material sheet;
forming an a-Si layer on the substrate;
oxygen ion implantation process of a certain depth is conducted on the a-Si layer; and
ELA process is conducted to transform a-Si layer into a poly-Si layer and an oxide insulating layer of which the oxide insulating layer is a silica insulating layer located within the poly-Si layer.

2. The method defined in claim 1, wherein the substrate is a soft metal foil, plastic film, polyester sheet, rayon cloth, or fiber cloth.

3. The method defined in claim 1, wherein the a-Si layer is deposited via PECVD.

4. The method defined in claim 1, wherein the oxygen ion implantation process is realized by means of SIMOX technology.

5. The method defined in claim 1, wherein the ELA process is realized by firstly pre-cleaning and then by laser annealing.

6. A flexible structure of LTPS-TFT display, which comprising:
a substrate, which is a soft metal foil;
a poly-Si layer, located on the substrate; and
an oxide insulating layer, located within the poly-Si layer.

7. The structure defined in claim 6, wherein said oxide insulating layer is a silica (SiO2) insulating layer.
